(19) United States
(12) Patent Application Publication
(10) Pub. No.: US 2008/0180849 A1
(43) Pub. Date: Jul. 31, 2008

(54) Magnetic head support, manufacturing methods therefor, and magnetic disk device

(75) Inventors: Shigeyoshi Umemiya, Kawasaki (JP); Masaharu Hida, Kawasaki (JP); Masao Kondo, Kawasaki (JP); Tsuyoshi Aoki, Kawasaki (JP)

Correspondence Address: GREER, BURNS & CRAIN, 300 S WACKER DR, 25TH FLOOR, CHICAGO, IL, 60606, US

(73) Assignee: Fujitsu Limited, Kawasaki-shi (JP)

(21) Appl. No.: 12/008,872

(22) Filed: Jan. 15, 2008

(30) Foreign Application Priority Data
Jan. 25, 2007 (JP) 2007-014464

(51) Int. Cl. G11B 5/48; H01L 41/24

(52) U.S. Cl. 360/240; 29/25.35

(57) ABSTRACT

According to an aspect of an embodiment, a method for manufacturing a magnetic head support having a piezoelectric device on a metal plate member comprises the steps of: providing a metal plate member; forming a piezoelectric layer of a piezoelectric material on the plate member at an elevated temperature; forming a first electrode layer of an electrical conducting material on the piezoelectric layer; and bending the metal plate member at a bending portion adjacent to the piezoelectric layer while the temperature is lowered from the elevated temperature after forming the piezoelectric layer.

### BACKGROUND OF THE INVENTION

1. Technical Field

The present invention relates to a magnetic disk device, more specifically, to a magnetic disk device having a magnetic head support fabricated by a simple process.

2. Description of the Related Art

The recording density of magnetic disk devices such as hard disk drives (HDDs) has been sharply increasing with technological improvements in magnetic disks, magnetic heads, signal processing, and the like. Under these circumstances, it has become important to maintain the flying height of a magnetic head at a very small and constant level.

A slider having a magnetic head is mounted on one end of a thin plate member called a suspension. The suspension has flexibility. When the suspension is deformed by a floating force generated at the slider, the suspension creates a force in an appropriate direction so as to cancel the deformation. The suspension has a bending portion that creates an urging force in a direction opposite to that of the floating force. The suspension is bent at the bending portion so that the slider becomes closer to a magnetic disk.

In order to maintain the flying height of the magnetic head at a very small and constant level, the force required to cancel the deformation of the suspension and the urging force of the suspension have to be precisely controlled. In order to obtain a precisely controlled urging force, the bending portion of the suspension needs to be bent at an accurate bending angle.

### SUMMARY

According to an aspect of an embodiment, a method for manufacturing a magnetic head support having a piezoelectric device on a metal plate member comprises the steps of: providing a metal plate member; forming a piezoelectric layer of a piezoelectric material on the plate member at an elevated temperature; forming a first electrode layer of an electrical conducting material on the piezoelectric layer; and bending the metal plate member at a bending portion adjacent to the piezoelectric layer while the temperature is lowered from the elevated temperature after forming the piezoelectric layer.

### BRIEF DESCRIPTION OF THE DRAWINGS

FIG. 1 is a plan view showing an interior of the magnetic disk device according to a first embodiment of the present invention;

FIG. 2 is a schematic view of a circuit for controlling the magnetic disk device according to the first embodiment of the present invention;

FIGS. 3A and 3B illustrate a magnetic head support according to the first embodiment of the present invention;

FIGS. 4A to 4C illustrate a manufacturing process of the magnetic head support according to the first embodiment of the invention;

FIGS. 5D and 5E illustrate the manufacturing process of the magnetic head support according to the first embodiment of the invention;

FIGS. 6F and 6G illustrate the manufacturing process of the magnetic head support according to the first embodiment of the invention;

FIG. 7H illustrates the manufacturing process of the magnetic head support according to the first embodiment of the invention;

FIG. 8 illustrates the manufacturing process of the magnetic head support according to the first embodiment of the invention;

FIG. 9 is a schematic view of a device (piezoelectric transducer) to be verified for its function as a piezoelectric sensor 26;

FIGS. 10A to 10C illustrate results of displacement of a suspension 6 in relation to the position and shape of piezoelectric devices;

FIGS. 11A and 11B illustrate a manufacturing process of a magnetic head support according to a second embodiment of the invention;

FIGS. 12C and 12D illustrate the manufacturing process of the magnetic head support according to the second embodiment of the invention;

FIGS. 13E and 13F illustrate the manufacturing process of the magnetic head support according to the second embodiment of the invention;

FIGS. 14G and 14H illustrate the manufacturing process of the magnetic head support according to the second embodiment of the invention;

FIGS. 15I and 15J illustrate the manufacturing process of the magnetic head support according to the second embodiment of the invention;

FIGS. 16K and 16L illustrate the manufacturing process of the magnetic head support according to the second embodiment of the invention; and

FIG. 17M illustrates the manufacturing process of the magnetic head support according to the second embodiment of the invention.

### DESCRIPTION OF THE PREFERRED EMBODIMENTS

Embodiments of the present invention will now be described in detail with reference to the drawings.

### First Embodiment

Magnetic Disk Device

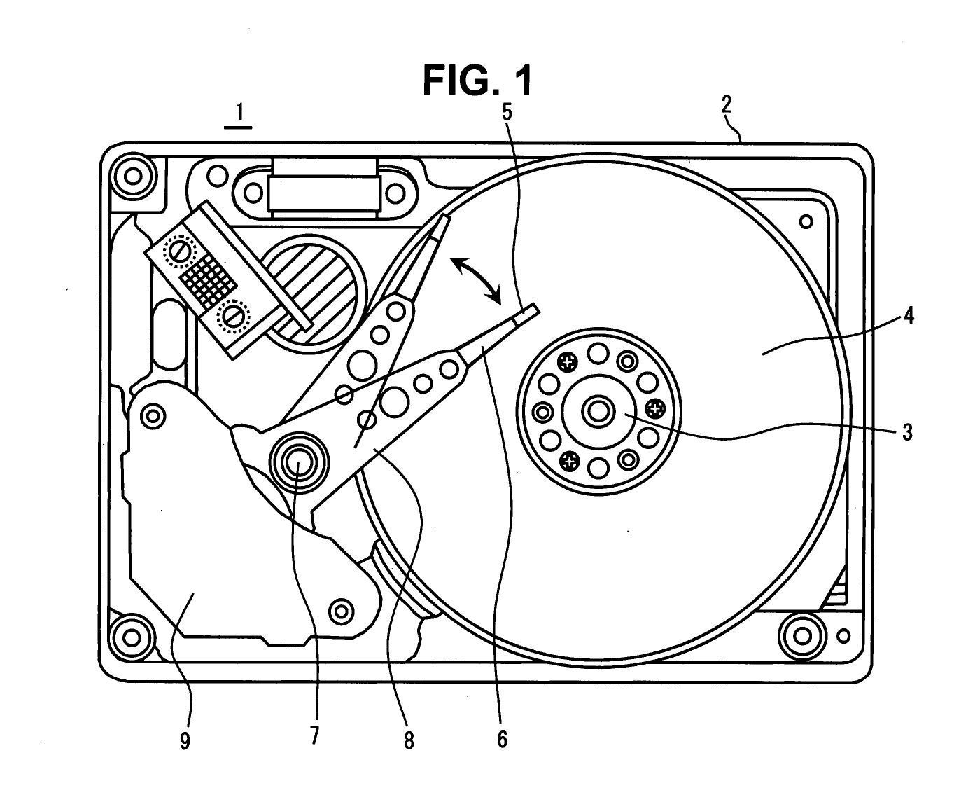

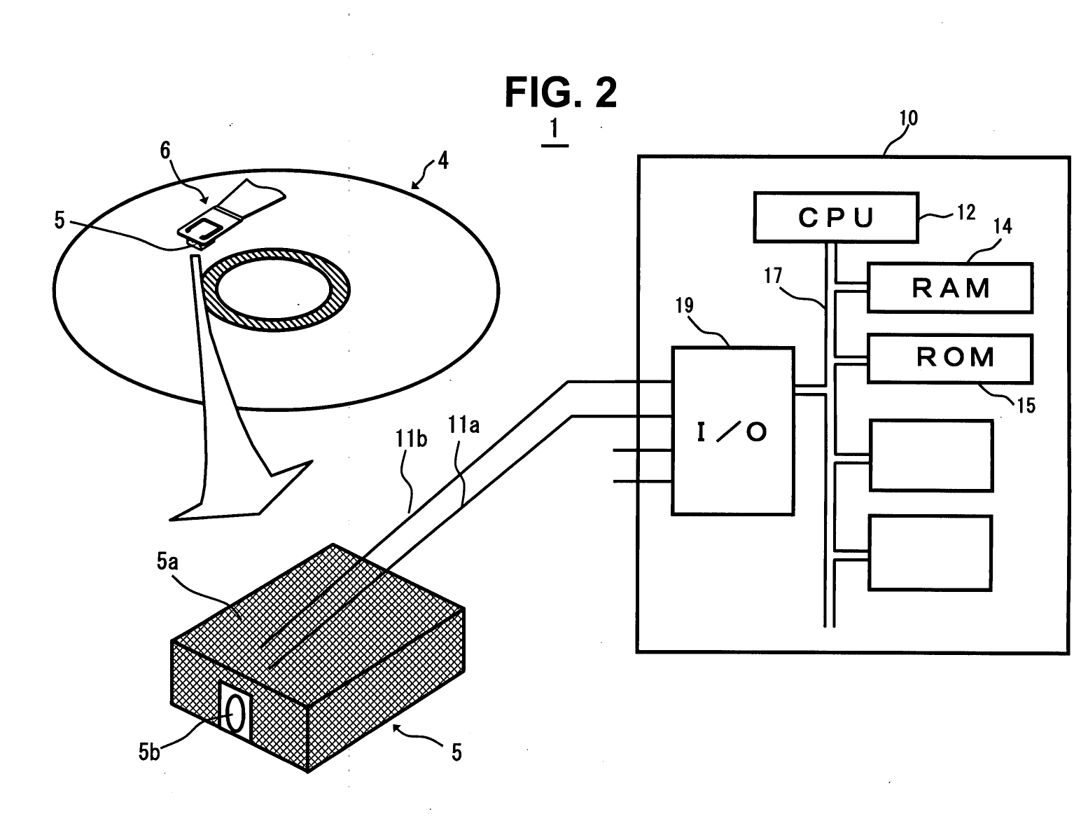

A magnetic disk device having a magnetic head support according to the present invention will now be described. FIG. 1 is a plan view showing an interior of the magnetic disk device according to a first embodiment of the present invention. FIG. 2 is a schematic view of a circuit for controlling the magnetic disk device according to the first embodiment of the present invention.

Referring to FIG. 1, a magnetic disk device 1 constitutes an HDD and has a housing 2 as a casing. The housing 2 contains a magnetic disk 4 mounted on a spindle 3 so as to be rotated, a slider 5 having a magnetic head for recording/reproducing information onto/from the magnetic disk 4, a suspension 6 for supporting the slider 5, a carriage arm 8 that has the suspension 6 fixed thereto and pivots about an arm axis 7 to move across the surface of the magnetic disk 4, and an electromagnetic actuator 9 for driving the carriage arm 8. A cover (not shown) is attached to the housing 2 to provide a space in which the aforementioned components are housed.

Referring to FIG. 2, the magnetic disk device 1 further has a control unit 10 for controlling operation of the magnetic disk device 1. The control unit 10 is mounted on, for example, a control board (not shown) provided in the housing 2. As shown in FIG. 2, the control unit 10 includes a central processing unit (CPU) 12, a random-access memory (RAM) 14 for temporarily storing data, etc., to be processed by the CPU 12, a read-only memory (ROM) 15 for storing a program for control, etc., an input/output circuit 19 for inputting/outputting signals to/from an external device, a bus 17 for transferring signals between components in the circuit, and the like.

As shown in FIG. 2, the slider 5 has a magnetic head 5b formed on a ceramic substrate 5a. The magnetic head 5b is, for example, connected to the input/output circuit 19 in the control unit 10 with wires 11a and 11b, and records information onto the magnetic disk 4 (writing operation) and reproduces information stored on the magnetic disk 4 (reading operation). In these reading and writing operations, the electromagnetic actuator 9 drives the carriage arm 8 to move the magnetic head 5b to a position above a desired track in the magnetic disk 4.

Specifically, these reading and writing operations are performed as follows. In the writing operation, the control unit 10 inputs an electric signal (an electrical recording signal) to the magnetic head 5b. The magnetic head 5b applies magnetic fields according to the recording signal to very small regions in the magnetic disk 4 and records information contained in the recording signal by aligning the magnetizing direction of these very small regions. In the reading operation, the magnetic head 5b extracts the information recorded in these very small regions as an electric signal (an electrical reproducing signal) according to the magnetization of these very small regions.

The CPU 12 precisely controls the flying height of the magnetic head provided on the slider 5 by slightly changing the bending angle of the bending portion using piezoelectric devices provided at the bending portion of the suspension 6. Details of the bending portion and the piezoelectric devices will be described below.

Magnetic Head Support

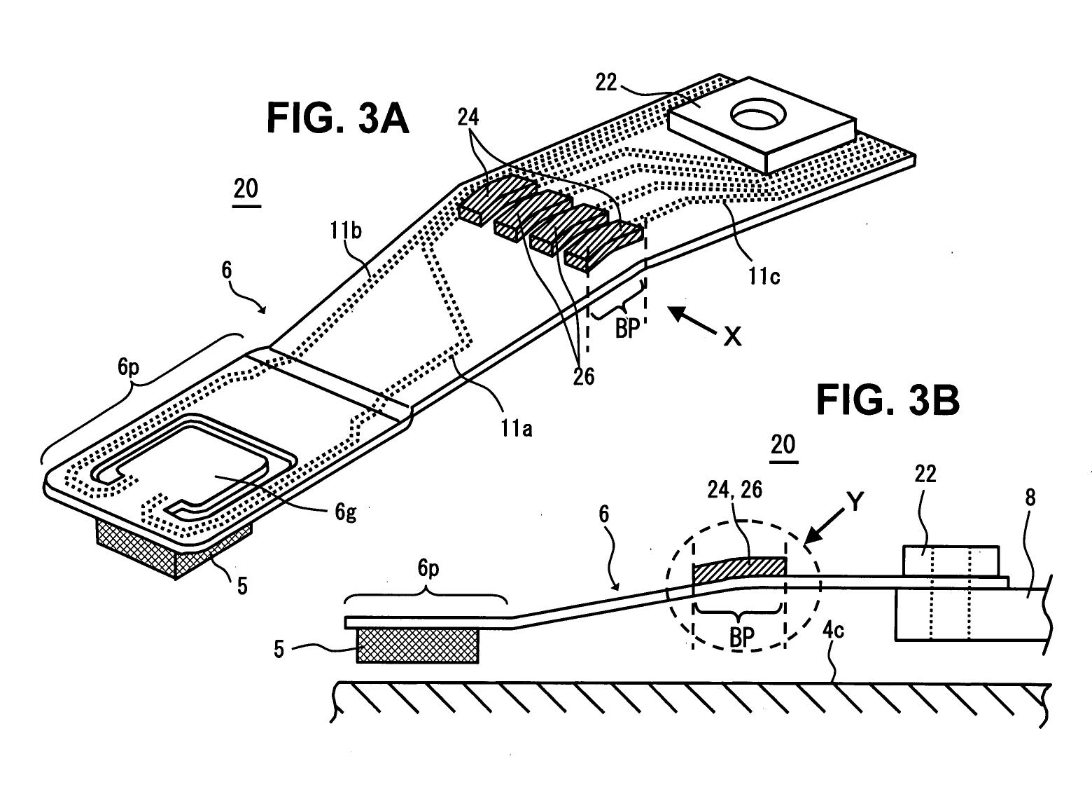

A magnetic head support according to the present invention will now be described. A magnetic head support may be referred to as a head gimbal assembly (HGA). FIGS. 3A and 3B are a perspective view and a side view of a magnetic head support, respectively, according to the first embodiment of the invention.

In general, as shown in FIGS. 3A and 3B, a structure in which a base plate 22, the slider 5, and the like are attached to the suspension 6 is referred to as a magnetic head support 20. A structure not yet attached with the base plate 22 and slider 5, namely, the suspension 6 alone, may also be referred to as the magnetic head support 20. Or, a structure in which one of the base plate 22 and the slider 5 is attached to the suspension 6 may also be referred to as the magnetic head support 20. Herein, the suspension 6 is a 20-μm-thick plate member made of stainless steel, for example. As shown, the base plate 22 is attached to one end of the suspension 6 on the carriage arm 8 side, and the slider 5 is attached to a tip 6p provided on the other end of the suspension 6. Specifically, the slider 5 having the magnetic head 5b is positioned so as to face the surface 4c of the magnetic disk and fixed to the gimbal 6g provided on the tip 6p.

Further, as shown in FIGS. 3A and 3B, the wires 11a and 11b provided on the suspension 6 are electrically connected to the electrodes (not shown) of the magnetic head 5b. Similarly, wires 11c provided on the suspension 6 are electrically connected to piezoelectric actuators 24 and piezoelectric sensors 26. The wires 11a, 11b, and 11c are all electrically connected to the control unit 10, so that the control unit 10 controls the magnetic head 5b, the piezoelectric actuators 24, and the piezoelectric sensors 26. The piezoelectric sensors 26 detect vibration of the suspension 6 (plate member).

Further, as shown in FIGS. 3A and 3B, the plurality of piezoelectric devices (the piezoelectric actuators 24 and the piezoelectric sensors 26) are disposed on the suspension 6. The piezoelectric actuators 24 and the piezoelectric sensors 26 are disposed on, for example, the surface opposite the surface facing the magnetic disk 4. The piezoelectric actuators 24 and the piezoelectric sensors 26 are desirably aligned in a row as shown in FIGS. 3A and 3B. Alternatively, a pair of the piezoelectric actuator 24 and the piezoelectric sensor 26, or, only one piezoelectric actuator 24 may be disposed. With the above-described arrangement, the suspension 6 is bent at a position provided with the piezoelectric actuators 24 and the piezoelectric sensors 26 at a predetermined angle to form a bending portion BP.

Manufacturing Process (First Embodiment)

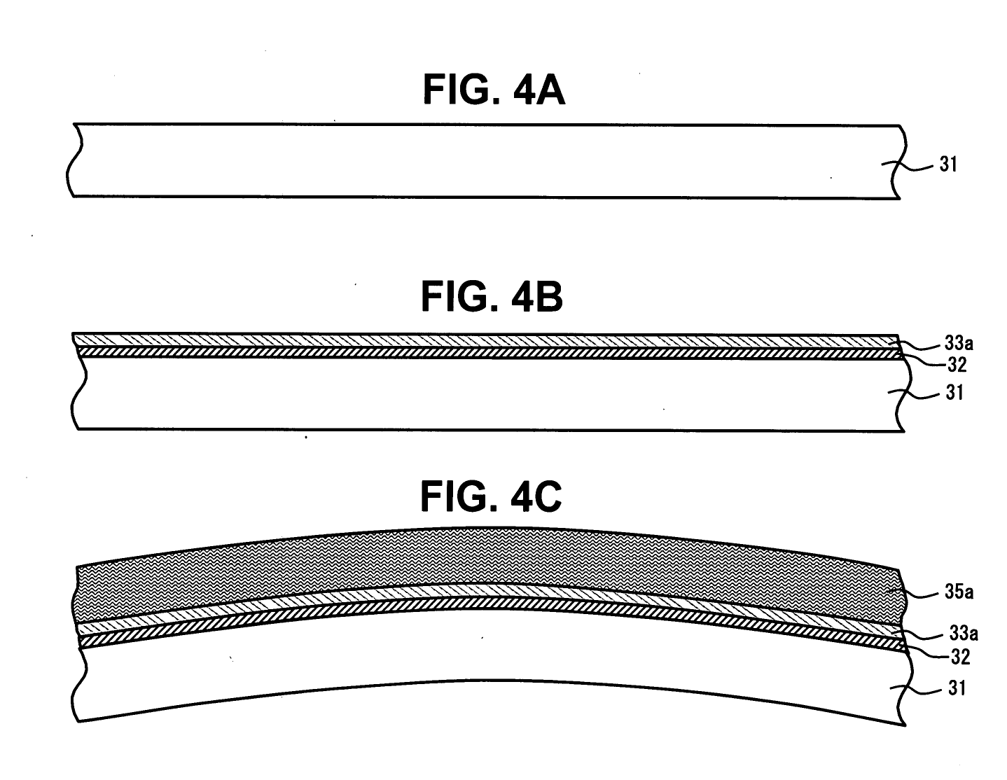

A manufacturing process of a magnetic head support according to the present invention will now be described. FIGS. 4 to 8 illustrate a manufacturing process of a magnetic head support according to the first embodiment of the invention. FIGS. 4 to 8 illustrate a portion Y shown in FIG. 3B viewed in the X-direction shown in FIG. 3A.

Step 1-1

Referring to FIG. 4A, a thin-plate substrate 31 is prepared. The substrate 31 is a 20-μm-thick plate made of stainless steel, for example. An example of stainless steel (SUS) suitable for the substrate 31 is SUS304 containing 18% chromium (Cr) and 8% nickel (Ni).

Step 1-2

Referring to FIG. 4B, an insulating layer 32 and a lower electrode layer (a second electrode layer) 33a are formed on the substrate 31. First, for example, using sputtering, a silica (SiO₂) film or an alumina (Al₂O₃) film as the insulating layer 32 is formed on the substrate 31. The thickness of the insulating layer 32 is, for example, about 200 nm. Then, for example, using sputtering, a platinum (Pt) film as the lower electrode layer 33a is formed on the insulating layer 32. The thickness of the lower electrode layer 33a is about 200 nm. The lower electrode layer 33a does not necessarily have to be formed by sputtering, but may be formed by vacuum deposition or the like. The lower electrode layer 33a does not necessarily have to be composed of a refractory metal, such as platinum, but may be composed of a chemically stable precious metal, such as gold (Au), iridium (Ir), or the like. Strontium ruthenate (SrRuO₃), titanium nitride (TiN), or the like may also be used for the lower electrode layer 33a.

Step 1-3

Referring to FIG. 4C, for example, using sputtering, a ceramic amorphous film as a piezoelectric layer 35a is formed on the lower electrode layer 33a. The thickness of the piezoelectric layer 35a is, for example, about 2 μm. The piezoelectric layer 35a does not necessarily have to be formed by sputtering, but may be formed by pulsed laser deposition, metal organic chemical vapor deposition (MOCVD), or the like. In the case where the substrate 31 is used as a lower electrode (a second electrode), the piezoelectric layer 35a may directly be formed on the substrate 31, without forming the insulating layer 32 and the lower electrode layer 33a.

In forming the piezoelectric layer 35a, for example, sputtering is performed at a temperature of about 600° C. The substrate 31 is also heated to about 600° C. at this time. In the case where the piezoelectric layer 35a is composed of a ferroelectric-oxide material having a perovskite crystal structure, such as lead zirconate titanate (PZT) or the like, the sputtering is preferably performed at a temperature higher than the crystallization temperature and lower than the structure-stabilizing temperature of the material, namely, between 450° C. and 800° C. By performing sputtering at the aforementioned temperature, the piezoelectric layer 35a of a polycrystalline structure is formed on the substrate 31.

When the substrate 31 and the piezoelectric layer 35a are cooled to room temperature (for example, about 25° C.) after formation of the piezoelectric layer 35a, the entirety of the substrate 31 is warped because of a difference in thermal expansion coefficient between the substrate 31 and the piezoelectric layer 35a. The substrate 31 shrinks more than the piezoelectric layer 35a, as shown in FIG. 4C. For example, a SUS material has a linear expansion coefficient of 14 to 18 ppm/° C., and a ceramic has a linear expansion coefficient of 6 to 7 ppm/° C.

Step 1-4

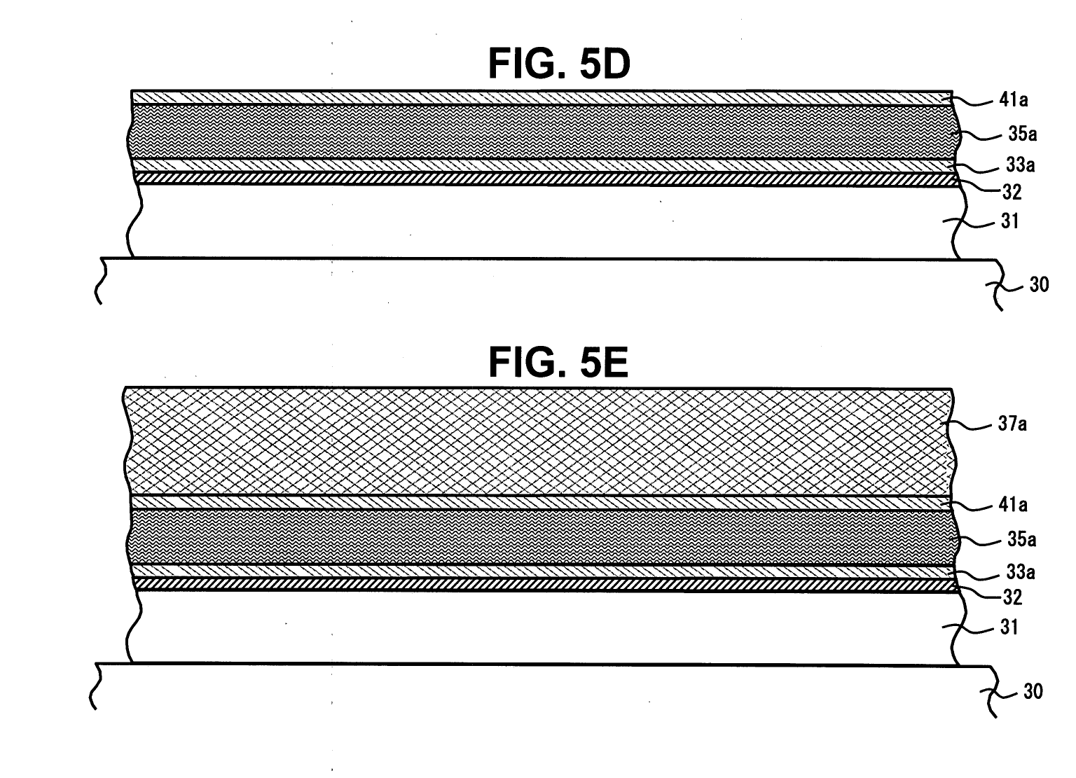

Referring to FIG. 5D, for example, using sputtering, a platinum film constituting an upper electrode layer (a first electrode layer) 41a is formed on the piezoelectric layer 35a. The thickness of the upper electrode layer 41a is, for example, about 200 nm. Because the method and materials for forming the upper electrode layer 41a are the same as those for the lower electrode layer 33a, description thereof will not be made here. From this step to Step 1-7 of the manufacturing process, the substrate 31 is fixed on a stage 30 so as to remove the warpage thereof and make it straight. For example, a vacuum chuck having a vacuum plate that is made of a porous ceramic is desirably used as the stage 30 so as to minimize the occurrence of deflection of the substrate 31.

Step 1-5

Referring to FIG. 5E, a photoresist constituting a resist layer 37a is applied on the upper electrode layer 41a. The thickness of the resist layer 37a is, for example, about 10 μm.

Step 1-6

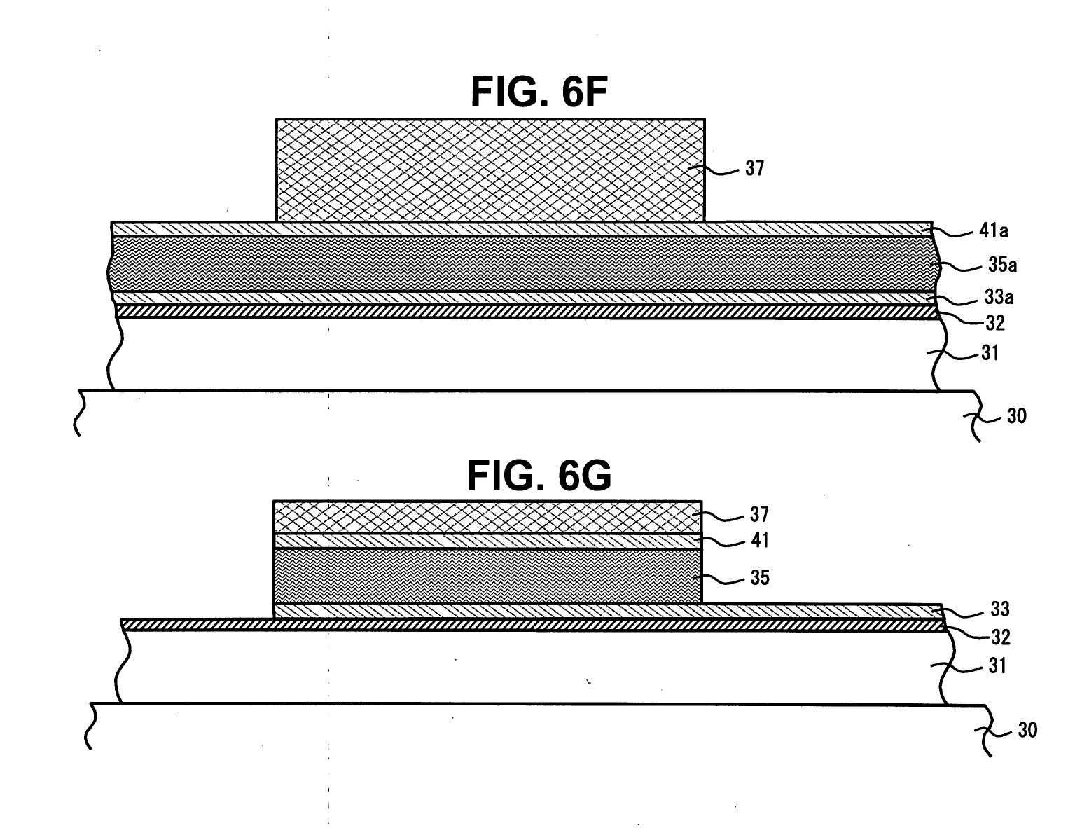

Referring to FIG. 6F, using photolithography, the resist layer 37a is patterned into the shapes of the piezoelectric actuators 24 and the piezoelectric sensors 26 to form a resist mask 37.

Step 1-7

Referring to FIG. 6G, using the resist mask 37, the upper electrode layer 41a and the piezoelectric layer 35a are etched. Although either of the dry and wet etching may be used, dry etching is desirable from the viewpoint of formation of erosion-free sidewalls. In the case of dry etching, inductively coupled plasma (ICP), electron cyclotron resonance (ECR), or the like is used. Argon (Ar) or the like may be used as an etching gas. Using this etching gas, the sidewalls of the piezoelectric layer 35a are formed to be substantially perpendicular to the substrate. In the case of wet etching, an aqueous solution of mixed acids such as hydrofluoric acid (HF)-nitric acid (HNO₃) and HF-hydrochloric acid (HCl), may be used as an etchant. In performing etching, a protective film composed of polyimide or the like is desirably formed on the substrate 31, if necessary, so as to prevent the portion surrounding the piezoelectric actuators 24 and the piezoelectric sensors 26 from being damaged.

Step 1-8

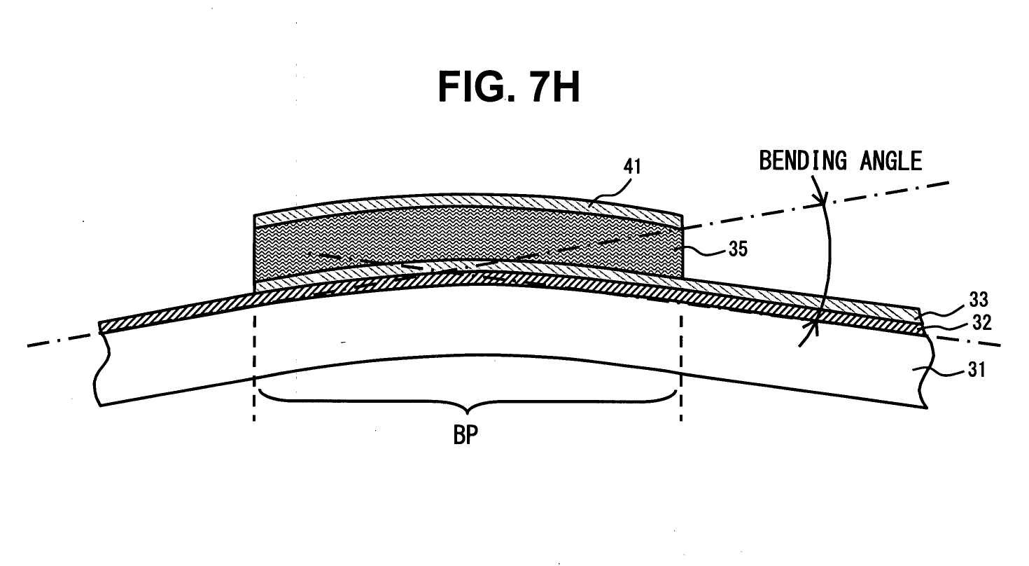

Referring to FIG. 7H, the resist mask 37 and the stage 30 are removed. When removed from the stage 30, the substrate 31 has the bending portion BP bent at, for example, 5 to 10 degrees at a portion provided with the piezoelectric actuators 24 and the piezoelectric sensors 26. The direction in which the bending portion BP is bent is the direction in which the slider 5 is urged towards the magnetic disk 4. The substrate 31, except for the bending portion BP, is not warped and extends straight. As shown in the drawings, the portions on both sides of the bending portion BP form the bending angle. The piezoelectric actuators 24 formed on the bending portion BP adjusts the bending angle of the bending portion BP and more precisely controls the bending angle.

Although not illustrated, the upper electrode 41 is connected to a wire formed on the substrate 31 before the stage 30 is removed. Specifically, a lead wire extends from the upper electrode 41 and a tip of the lead wire is connected to a pad (not shown) formed on the substrate 31. The pad is connected with a wire extending from the control unit 10 on the substrate 31. The substrate 31 provided with the piezoelectric actuators 24 and the piezoelectric sensors 26 is processed into the shape of the suspension 6 by wet etching. Alternatively, the substrate 31 may be cut into the shape of the suspension 6 using dicing saw. Although dicing is desirably performed before the stage 30 is removed, it may be performed after the stage 30 is removed.

Step 1-9

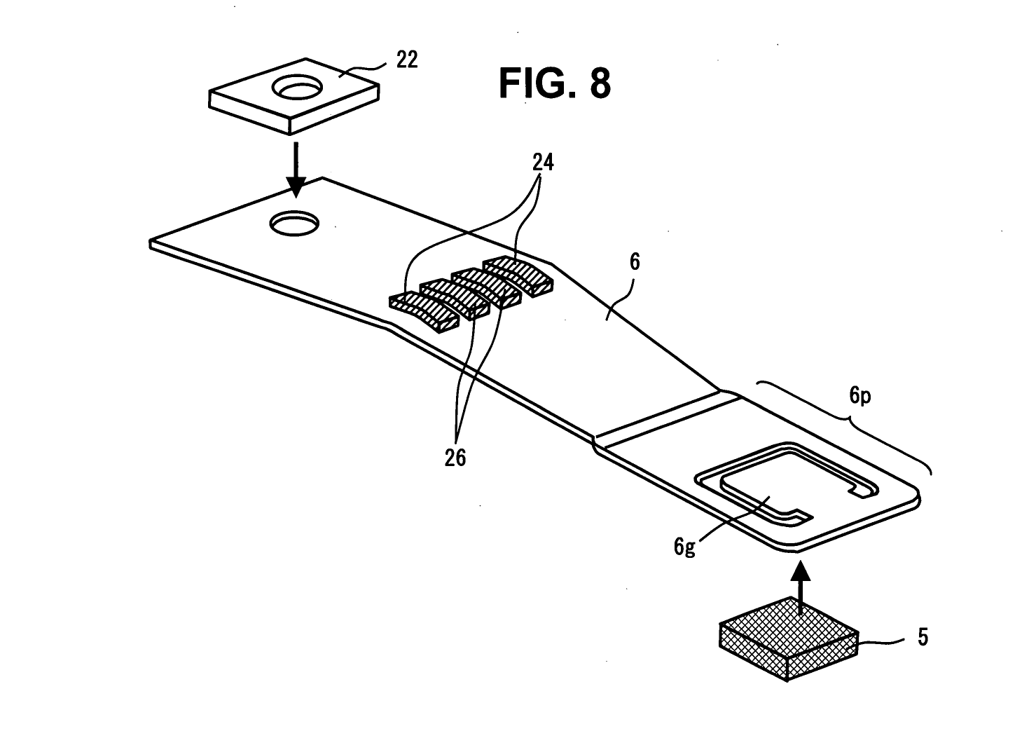

Referring to FIG. 8, the magnetic head support 20 is fabricated. Specifically, the magnetic head support 20 is completed by attaching the base plate 22 and the slider 5 to the suspension 6 (provided with the piezoelectric actuators 24 and the piezoelectric sensors 26) formed by performing the above-described steps.

Verification 1

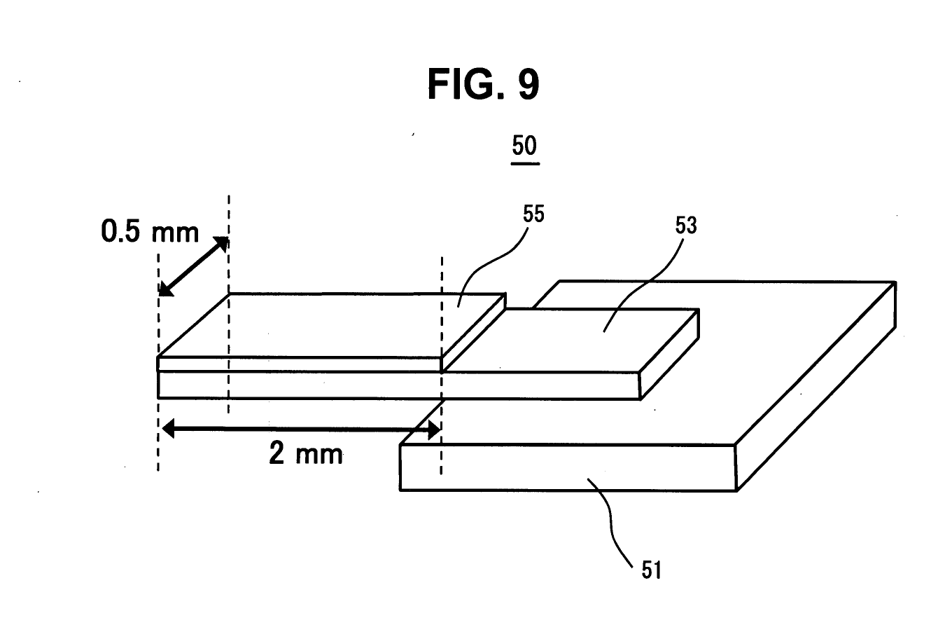

FIG. 9 is a schematic view of a device (piezoelectric transducer 50) to be verified for its function as the piezoelectric sensor 26. As shown in FIG. 9, the piezoelectric transducer 50 has an active portion having a size of 0.5 mm×2 mm. Fabrication steps of the piezoelectric transducer 50 and results of verification performed therewith will be described below.

One end of a 100-um-thick stainless steel substrate was fixed on a stage 51. Platinum was sputtered on the stainless steel substrate to form a lower electrode layer. Using the sol-gel method, a PZT material was deposited on the lower electrode layer to form a 1.5-μm-thick PZT film. Then, platinum was sputtered on the PZT film to form an upper electrode layer. Lastly, the stainless steel substrate was cut to provide a strip stainless steel substrate 53 provided with a PZT body 55 having a size of 0.5 mm×2 mm.

Next, a voltage of 20V was applied to the thus-fabricated piezoelectric transducer 50 to calculate “d31 piezoelectric constant” from the amount of displacement of one end of the stainless steel substrate 53. The calculation result was −50 pm/V. Further, the piezoelectric transducer 50 was mounted on a vibrator (not shown) to measure the characteristics thereof as a piezoelectric sensor. The result showed that the piezoelectric transducer 50 had an electrical charge sensitivity of 1.2 coulombs per unit of gravitational acceleration. Thus, the function of the piezoelectric transducer 50 as a piezoelectric sensor was verified.

Verification 2

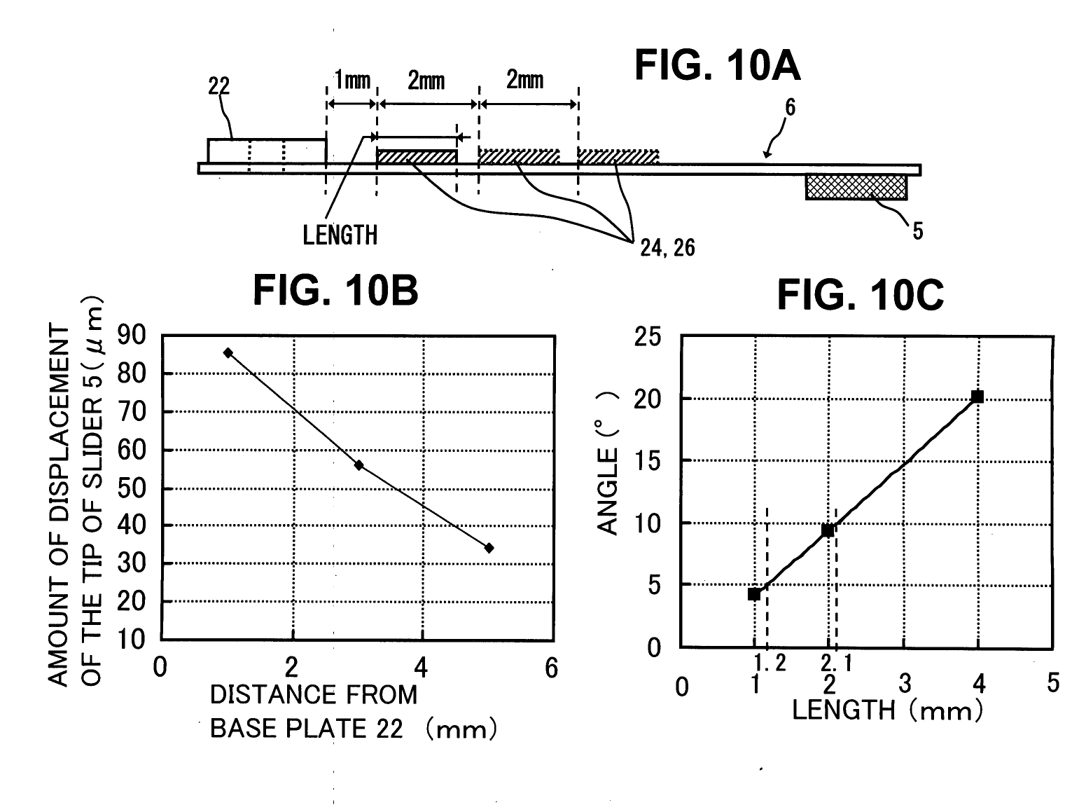

Next, the displacement behavior of the suspension 6 in relation to the position and the shape of the piezoelectric devices (the piezoelectric actuators 24 and the piezoelectric sensors 26) were verified. All the results of this verification were obtained by simulation. FIGS. 10A to 10C illustrate results of displacement of the suspension 6 in relation to the position and shape of the piezoelectric devices. FIG. 10B is a graph showing the relationship between the position of the piezoelectric devices and the amount of displacement of the tip of the slider. FIG. 10C is a graph showing the relationship between the shape of the piezoelectric devices and the bending angle of the slider.

As shown in FIG. 10B, the farther the piezoelectric devices are positioned from the end of the base plate 22, the smaller the amount of displacement of the tip of the slider 5.

As shown in FIG. 10C, the larger the length of the piezoelectric devices, the larger the bending angle of the suspension. It can be understood from the graph of FIG. 10C, the length of the piezoelectric devices need to be 1.2 mm to 2.1 mm to obtain a bending angle of between 5 to 10 degrees.

In the present embodiment, the piezoelectric actuators 24 or the piezoelectric sensors 26 of a predetermined shape is formed on the suspension 6. At the same time, the bending portion BP having a predetermined bending angle is formed. Alternatively, the piezoelectric actuators 24 and the piezoelectric sensors 26 may simultaneously be formed on the suspension 6. In the case of the piezoelectric actuators 24 and the piezoelectric sensors 26 being formed on the suspension 6, for example, the piezoelectric actuators 24 and the piezoelectric sensors 26 are controlled by the control unit 10, whereby the flying height of the magnetic head 5b can be precisely controlled.

The flying height of the magnetic head 5b is controlled as follows. The piezoelectric sensors 26 detect the displacement of the bending angle of the bending portion BP. The detection result is sent to the piezoelectric actuators 24 via the control unit 10. The piezoelectric actuators 24 adjust the bending angle of the bending portion BP according to the detection result and control the flying height of the magnetic head 5b.

According to the method for manufacturing the magnetic head support of the embodiment, the bending portion is provided in the plate member when the piezoelectric devices are formed. That is, the bending portion for urging the slider towards a surface of a magnetic disk can be formed by a simple process.

### Second Embodiment

The magnetic head support according to the present embodiment is formed by the same manufacturing process as the first embodiment except for the steps described below.

### Manufacturing Process (Second Embodiment)

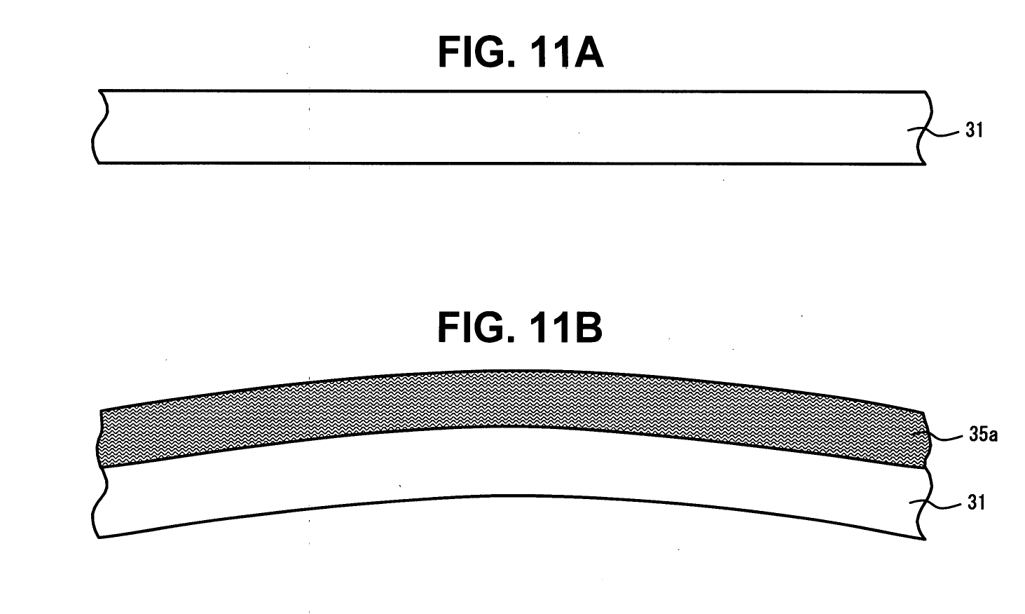

A manufacturing process of a magnetic head support according to the invention will now be described. FIGS. 11 to 17 illustrate the manufacturing process of the magnetic head support according to a second embodiment of the invention. FIGS. 4 to 8 illustrate a portion Y shown in FIG. 3B viewed in the X-direction shown in FIG. 3A.

Step 2-1

Referring to FIG. 11A, a thin substrate 31 is prepared. The substrate 31 is a 20-μm-thick plate made of stainless steel, for example. An example of stainless steel suitable for the substrate 31 is SUS304 containing 18% Cr and 8% Ni.

Step 2-2

Referring to FIG. 11B, for example, using sputtering, a ceramic amorphous film as a piezoelectric layer 35a is formed on the substrate 31. The thickness of the piezoelectric layer 35a is, for example, about 2 μm. The piezoelectric layer 35a does not necessarily have to be formed by sputtering, but may be formed by pulsed laser deposition, MOCVD, or the like. In the case where the substrate 31 is not used as an electrode (a lower electrode of the piezoelectric devices), an insulating layer 32 and a lower electrode layer 33a may be formed between the substrate 31 and the piezoelectric layer 35a, as described in the first embodiment.

In forming the piezoelectric layer 35a, for example, sputtering is performed at a temperature of about 600° C. The substrate 31 is heated to about 600° C. at this time. In the case where the piezoelectric layer 35a is composed of ferroelectric-oxide material having a perovskite crystal structure, such as PZT or the like, the sputtering is preferably performed at a temperature higher than the crystallization temperature and lower than the structure-stabilizing temperature of the material, namely, between 450° C. and 800° C. By performing sputtering at the aforementioned temperature, the piezoelectric layer 35a of a polycrystalline structure is formed on the substrate 31.

When the substrate 31 and the piezoelectric layer 35a are cooled to room temperature (for example, about 25° C.) after formation of the piezoelectric layer 35a, the entirety of the substrate 31 is warped because of a difference in thermal expansion coefficient between the substrate 31 and the piezoelectric layer 35a. The substrate 31 shrinks more than the piezoelectric layer 35a, as shown in FIG. 4C. For example, a SUS material has a linear expansion coefficient of 14 to 18 ppm/° C., and a ceramic has a linear expansion coefficient of 6 to 7 ppm/° C.

Step 2-3

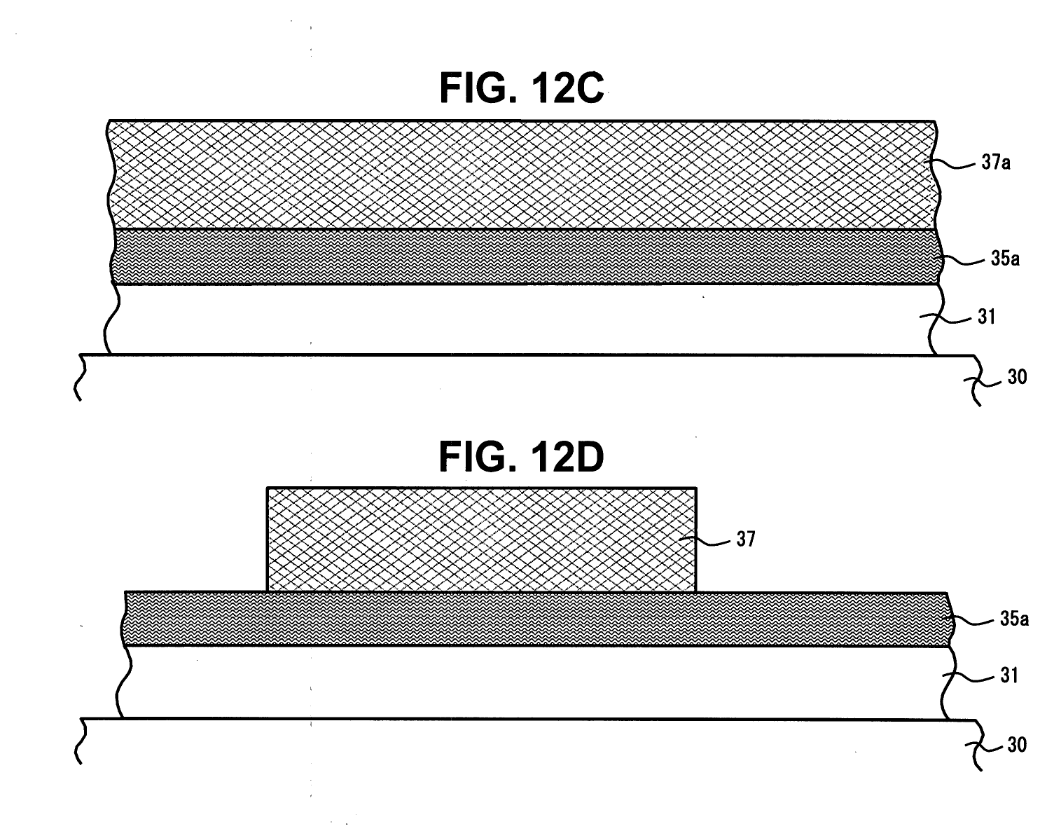

Referring to FIG. 12C, a photoresist constituting a resist layer 37a is applied on the piezoelectric layer 35a. The thickness of the resist layer 37a is, for example, about 10 μm.

Step 2-4

Referring to FIG. 12D, using photolithography, the resist layer 37a is patterned into the shapes of the piezoelectric actuators 24 and the piezoelectric sensors 26 to form a resist mask 37.

Step 2-5

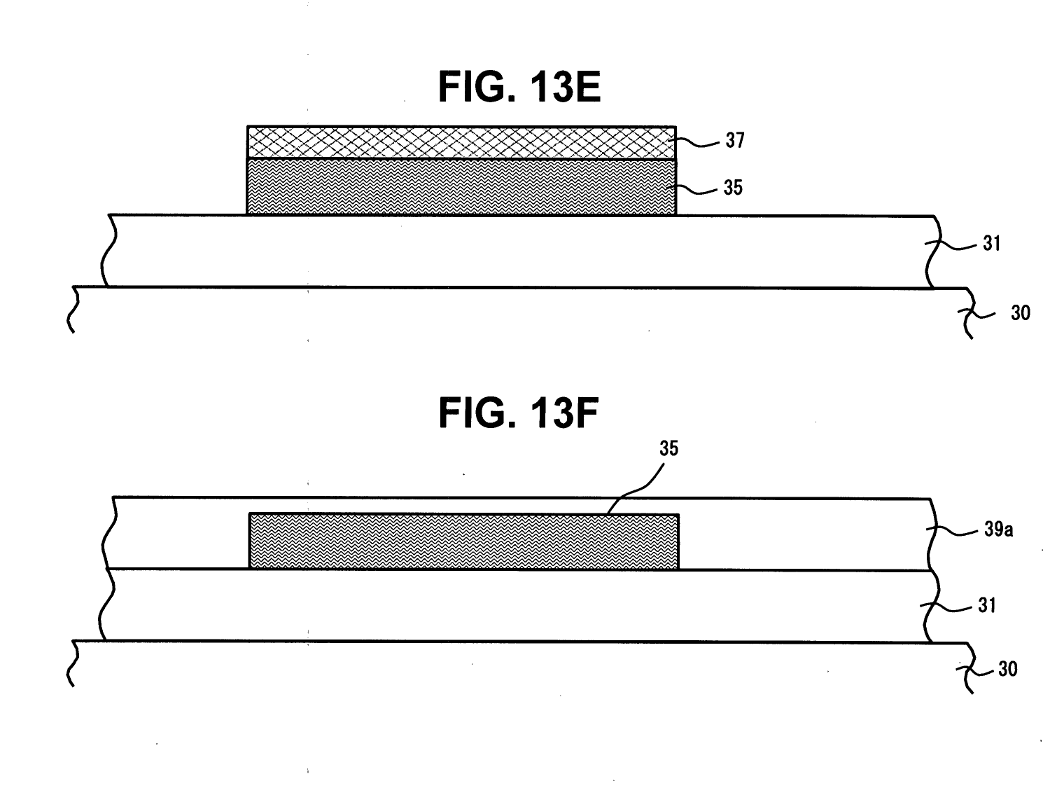

Referring to FIG. 13E, using the resist mask 37, the piezoelectric layer 35a is etched. Although either dry and wet etching may be used, dry etching is desirable from the viewpoint of formation of erosion-free sidewalls. In the case of dry etching, ICP, ECR, or the like is used. Argon or the like may be used as an etching gas. Using this etching gas; the sidewalls of the piezoelectric layer 35a are formed to be substantially perpendicular to the substrate. In the case of wet etching, an aqueous solution of mixed acids such as hydrofluoric acid (HF)-nitric acid (HNO₃) and HF-hydrochloric acid (HCl), may be used as an etchant. In performing etching, a protective film composed of polyimide or the like is desirably formed on the substrate 31, if necessary, so as to prevent the portion surrounding the piezoelectric actuators 24 and the piezoelectric sensors 26 from being damaged.

Step 2-6

Referring to FIG. 13F, after the resist mask 37 is removed, for example, using spin-coating or dipping, a protective film layer 39a composed of a resin is formed so as to cover the piezoelectric body 35. More specifically, for example, a low-viscosity varnish prepared by dissolving acrylic resin, epoxy resin, polyimide, or the like in a solvent is applied on the piezoelectric body 35.

Step 2-7

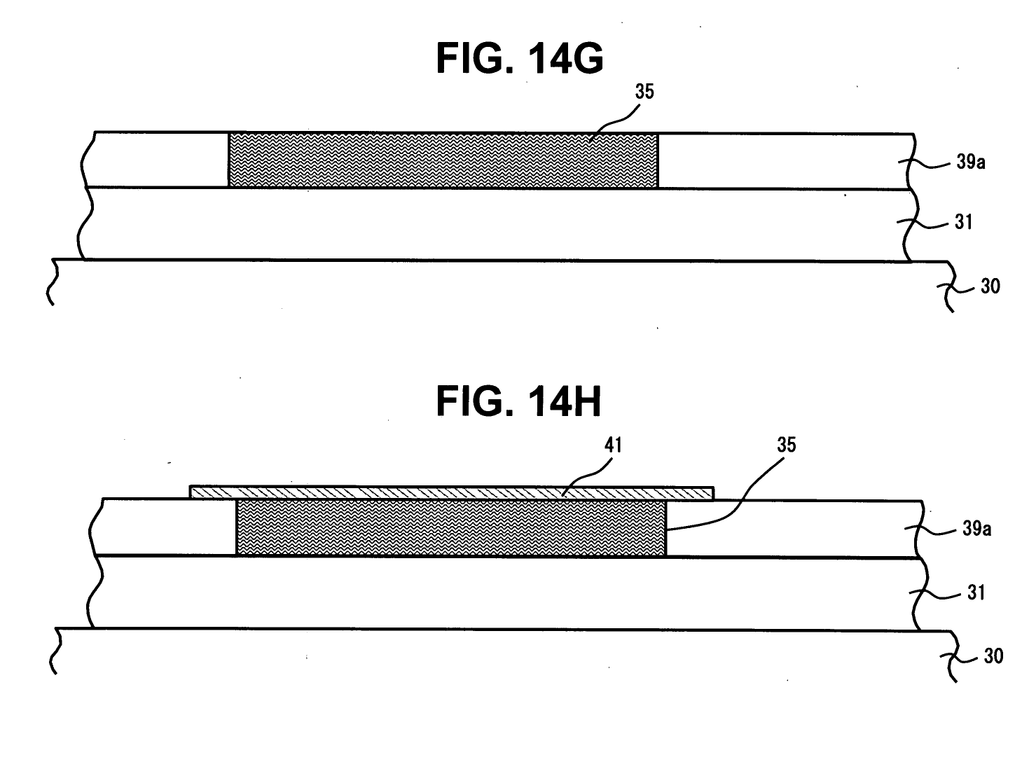

Referring to FIG. 14G, for example, using reactive ion etching (RIE), chemical mechanical polishing (CMP), or the like, the height of the protective film layer 39a is reduced to the height of the piezoelectric body 35. More specifically, using the aforementioned methods, the protective film layer 39a is removed until the top surface of the piezoelectric body 35 is exposed.

Step 2-8

Referring to FIG. 14H, for example, using photolithography, an upper electrode (a first electrode) 41 is formed on the piezoelectric body 35. The upper electrode 41 is, using sputtering or the like, formed at normal temperature so that the protective film layer 39 will not be deformed or vaporized.

Step 2-9

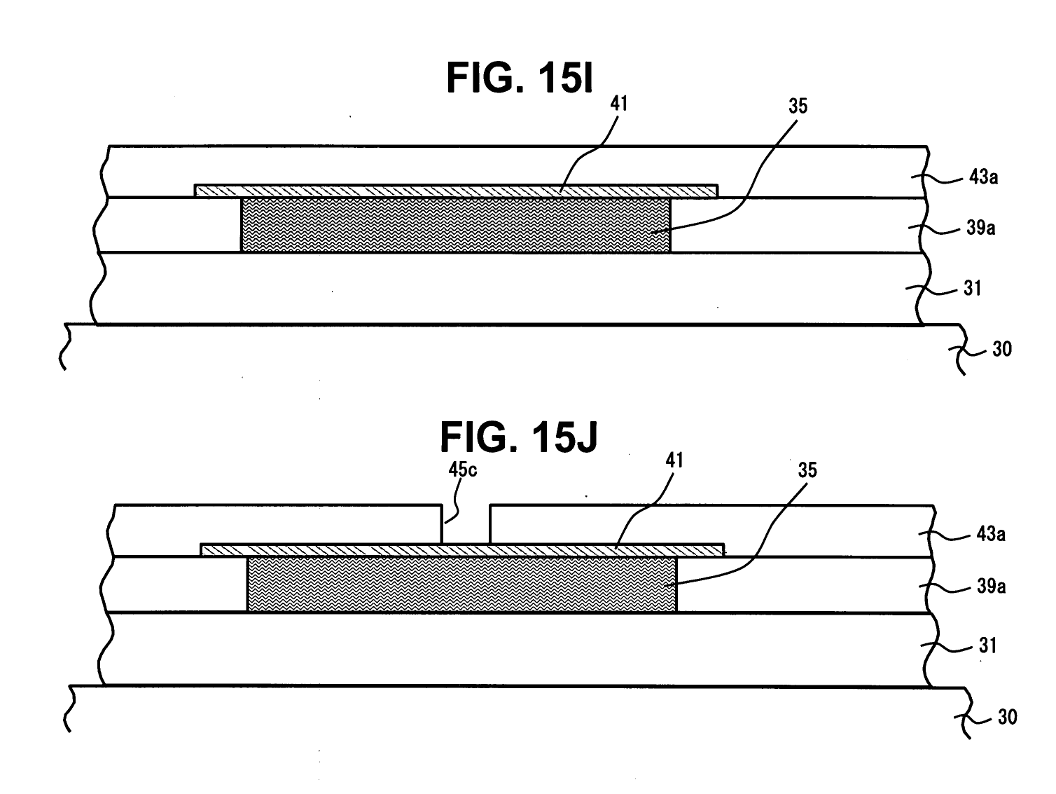

Referring to FIG. 15I, a protective film layer 43a composed of an insulating material is formed so as to cover the upper electrode 41. As the protective film layer 43a, for example, a polymer film, a silica film, an alumina film, or the like may be used. For a polymer film, spin-coating or dipping is employed. For a silica film and an alumina film, sputtering is employed.

Step 2-10

Referring to FIG. 15J, a via hole 45 allowing for contact with the upper electrode 41 is provided in the protective film layer 43a. To provide the via hole 45c, a photoresist mask (not shown) is formed on the protective film layer 43a leaving an uncoated portion, and etching such as RIE is performed thereon.

Step 2-11

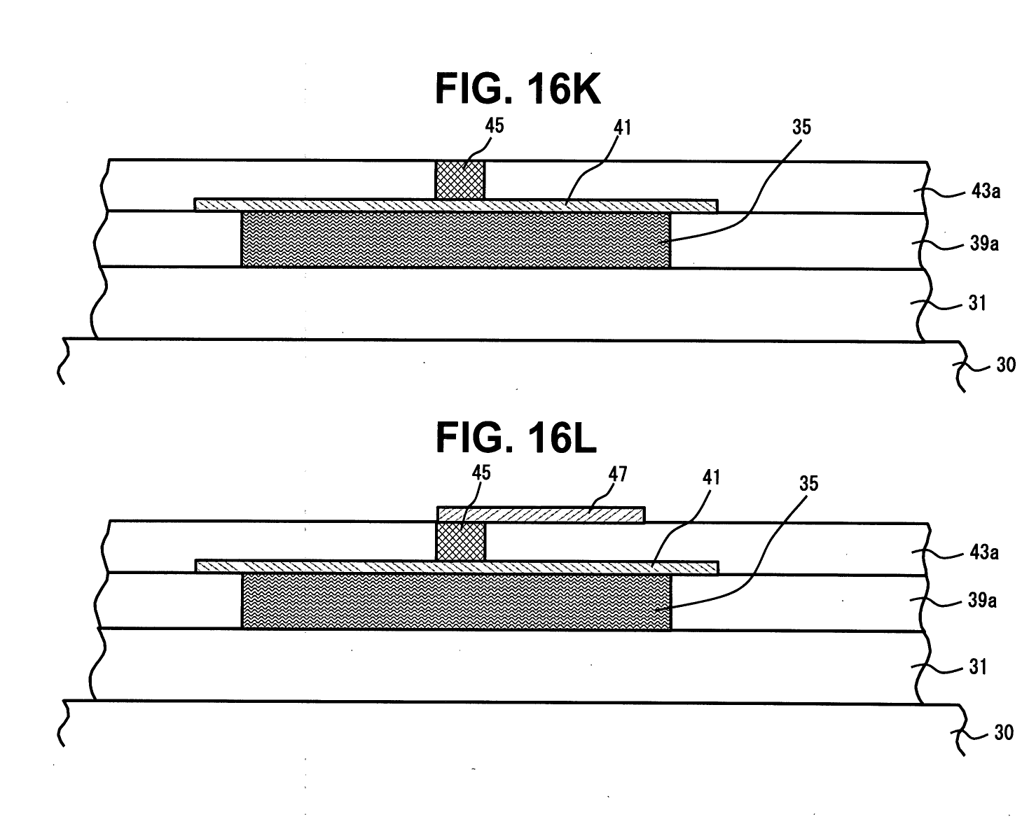

Referring to FIG. 16K, using sputtering or the like, the via hole 45c is filled with a metal such as gold. Then, any unnecessary portion of the metal is removed to provide a via contact 45.

Step 2-12

Referring to FIG. 16L, for example, using photolithography, an extending wire 47 is formed on the piezoelectric body 35. It is possible that a pad (not shown) be formed on a portion of the extending wire 47, and a lead wire (not shown) extending from the suspension 6 is bonded to the pad.

Step 2-13

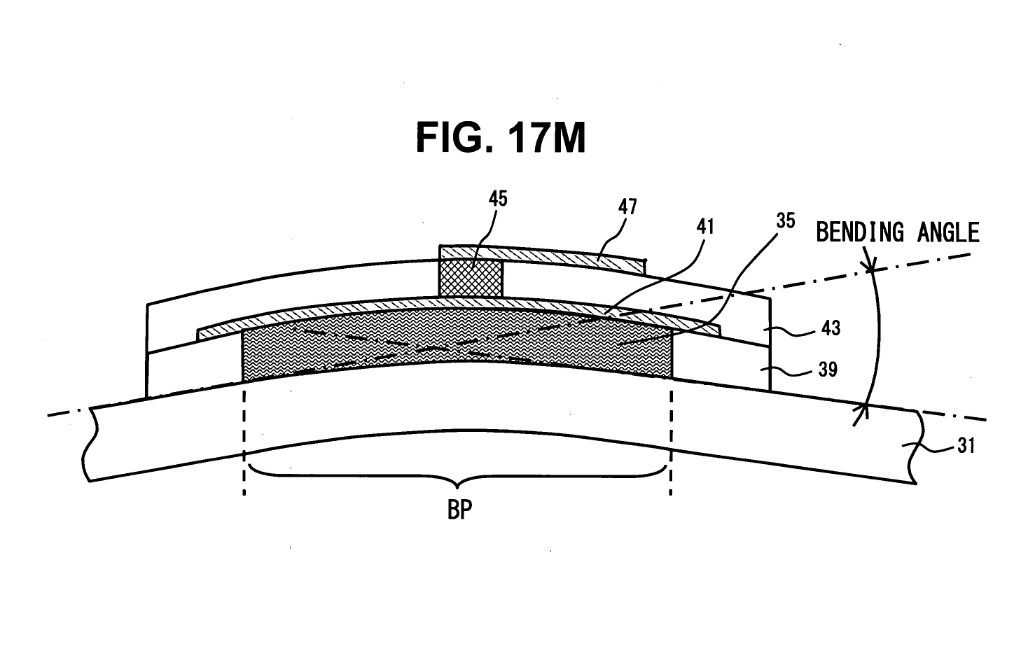

Referring to FIG. 17M, sidewalls of the protective film layer 39a and the protective film layer 43a are formed to be substantially perpendicular to the substrate. Thereafter, the stage 30 is removed. When removed from the stage 30, the substrate 31 has the bending portion BP bent at, for example, 5 to 10 degrees at a portion provided with the piezoelectric actuators 24 and the piezoelectric sensors 26. The substrate 31, except for the bending portion BP, is not warped and extends straight.

According to the method for manufacturing the magnetic head support of the embodiment, the bending portion is provided in the plate member when the piezoelectric devices are formed. That is, the bending portion for urging the slider towards a surface of a magnetic disk can be formed by a simple process.

In addition, as shown in the embodiment, the piezoelectric actuators 24 and the piezoelectric sensors 26 are covered by a protective film. This can prevent the piezoelectric actuators 24 and the piezoelectric sensors 26 from being degraded by absorption of moisture or similar reasons. Further, the flying height of the magnetic head 5b can be more assuredly controlled.

What is claimed is:

1. A method for manufacturing a magnetic head support having a piezoelectric device on a metal plate member, the method comprising the steps of:
providing a metal plate member;
forming a piezoelectric layer of a piezoelectric material on the plate member at an elevated temperature;
forming a first electrode layer of an electrical conducting material on the piezoelectric layer; and
bending the metal plate member at a bending portion adjacent to the piezoelectric layer while the temperature is lowered from the elevated temperature after forming the piezoelectric layer.

2. The method according to claim 1, wherein the piezoelectric device is an actuator for changing an angle formed between both sides of the metal plate member at the bending portion.

3. The method according to claim 1, wherein the piezoelectric device is a sensor for detecting a vibration of the plate member.

4. The method according to claim 1, wherein the heating is performed at a temperature higher than a crystallization temperature and lower than a structure-stabilizing temperature of the piezoelectric material.

5. The method according to claim 1, further comprising the steps of:
forming an insulating layer of an insulating material on the plate member before the step of forming the piezoelectric layer; and
forming a lower electrode layer of an electrical conducting material on the insulating layer.

6. The method according to claim 1, wherein the piezoelectric layer comprises a ceramic material, and the plate member comprises a stainless steel.

7. The method according to claim 1, wherein the piezoelectric layer comprises a ferroelectric-oxide material having a perovskite crystal structure.

8. A magnetic head support comprising:
a metal plate member; and
a piezoelectric device including:
a piezoelectric body formed of a piezoelectric material on the metal plate member, and
a first electrode formed of an electrical conducting material on the piezoelectric body, the metal plate member being bent at a portion adjacent to the piezoelectric device.

9. The magnetic head support according to claim 8, wherein the piezoelectric device performs as an actuator for changing in an angle between both sides of the metal plate member at the portion.

10. The magnetic head support according to claim 8, wherein the piezoelectric device is a sensor for detecting a vibration of the plate member.

11. The magnetic head support according to claim 8, wherein the heating is performed at a temperature higher than a crystallization temperature and lower than a structure-stabilizing temperature of the piezoelectric material.

12. The magnetic head support according to claim 8, further comprising:
an insulator formed of an insulating material on the plate member between the plate member and the piezoelectric body; and
a lower electrode layer of an electrical conducting material on the insulator.

13. The magnetic head support according to claim 8, wherein the piezoelectric body comprises a ceramic material, and the plate member comprises a stainless steel.

14. The magnetic head support according to claim 8, wherein the piezoelectric body comprises a ferroelectric-oxide material having a perovskite crystal structure.

15. A magnetic disk device comprising:
a magnetic head support including
a metal plate member, and
a piezoelectric device having
a piezoelectric body formed of a piezoelectric material on the metal plate member, and
a first electrode formed of an electrical conducting material on the piezoelectric body, the metal plate member being bent at a portion adjacent to the piezoelectric device.
